(19) United States
(12) Patent Application Publication
(10) Pub. No.: US 2025/0226206 A1
(43) Pub. Date: Jul. 10, 2025

(54) METHOD OF PROCESSING SUBSTRATE, METHOD OF MANUFACTURING SEMICONDUCTOR DEVICE, SUBSTRATE PROCESSING SYSTEM, AND RECORDING MEDIUM

(71) Applicant: Kokusai Electric Corporation, Tokyo (JP)

(72) Inventor: Daigo YAMAGUCHI, Toyama-shi (JP)

(73) Assignee: Kokusai Electric Corporation, Tokyo (JP)

(21) Appl. No.: 19/089,228

(22) Filed: Mar. 25, 2025

Related U.S. Application Data
(63) Continuation of application No. PCT/JP2022/047756, filed on Dec. 23, 2022.

(51) Int. Cl. H01L 21/02; C23C 16/52; H01L 21/306

(52) U.S. Cl. CPC H01L 21/0228; C23C 16/52; H01L 21/02211; H01L 21/30604

(57) ABSTRACT

There is provided a technique that includes: (a) forming a third film on a first film and a second film formed on a surface of the substrate by supplying a precursor, a first reactant, and a second reactant to the substrate under a condition in which thermal decomposition of the precursor does not occur and physical adsorption of the precursor occurs more predominantly than chemical adsorption of the precursor when the precursor is present alone; and (b) removing the first film while retaining the second film and the third film by exposing the surface of the substrate where the third film is formed on the first film and the second film to an etching agent that reacts with the first film.

### CROSS-REFERENCE TO RELATED APPLICATION

This application is a Bypass Continuation application of PCT International Application No. PCT/JP2022/047756, filed on Dec. 23, 2022 and designating the United States, the disclosure of which is incorporated herein in its entirety by reference.

### TECHNICAL FIELD

The present disclosure relates to a method of processing a substrate, a method of manufacturing a semiconductor device, a substrate processing system, and a recording medium.

### BACKGROUND

In the related art, as a process of manufacturing a semiconductor device, a process of forming an air gap on a substrate is sometimes performed.

As semiconductor devices become miniaturized, there is a strong demand for precisely forming an air gap on a substrate with high accuracy.

### SUMMARY

Some embodiments of the present disclosure provide a technique capable of precisely forming an air gap with high accuracy.

According to some embodiments of the present disclosure, there is provided a technique that includes: (a) forming a third film on a first film and a second film formed on a surface of the substrate by supplying a precursor, a first reactant, and a second reactant to the substrate under a condition in which thermal decomposition of the precursor does not occur and physical adsorption of the precursor occurs more predominantly than chemical adsorption of the precursor when the precursor is present alone; and (b) removing the first film while retaining the second film and the third film by exposing the surface of the substrate where the third film is formed on the first film and the second film to an etching agent that reacts with the first film.

### BRIEF DESCRIPTION OF DRAWINGS

The accompanying drawings, which are incorporated in and constitute a part of the specification, illustrate embodiments of the present disclosure.

FIG. 1 is a schematic diagram of a vertical process furnace of a substrate processing system which may be used in each of embodiments of the present disclosure, in which a portion of a process furnace is shown in a vertical cross-sectional view.

FIG. 2 is a schematic diagram of a vertical process furnace of a substrate processing system which may be used in each of embodiments of the present disclosure, in which a portion of the process furnace is shown in a cross-sectional view taken along line A-A in FIG. 1.

FIG. 3 is a schematic diagram of a controller of a substrate processing system which may be used in each of embodiments of the present disclosure, in which a control system of the controller is shown in a block diagram.

FIG. 4 is a diagram showing a substrate processing sequence in some embodiments of the present disclosure.

FIG. 5A is a partial cross-sectional enlarged view showing a surface of a wafer in some embodiments of the present disclosure including a first film and a second film formed on the surface. FIG. 5B is a partial cross-sectional enlarged view showing the surface of the wafer in some embodiments of the present disclosure after forming an initial layer on the first film and the second film. FIG. 5C is a partial cross-sectional enlarged view showing the surface of the wafer in some embodiments of the present disclosure after forming a third film on the initial layer. FIG. 5D is a partial cross-sectional enlarged view showing the surface of the wafer in some embodiments of the present disclosure after forming an air gap by removing the first film while retaining the second and third films. FIG. 5E is a partial cross-sectional enlarged view showing the surface of the wafer in some embodiments of the present disclosure after forming a fourth film on the third film.

FIG. 6A is a partial cross-sectional enlarged view of a surface of a wafer in other embodiments of the present disclosure including a first film and a second film on the surface.

FIG. 6B is a partial cross-sectional enlarged view of the surface of the wafer in other embodiments of the present disclosure after forming an initial layer on the first film and the second film. FIG. 6C is a partial cross-sectional enlarged view of the surface of the wafer in other embodiments of the present disclosure after forming a third film on the initial layer. FIG. 6D is a partial cross-sectional enlarged view of the surface of the wafer in other embodiments of the present disclosure after forming an air gap by removing a portion of the first film while retaining the second film and the third film. FIG. 6E is a partial cross-sectional enlarged view of the surface of the wafer in other embodiments of the present disclosure after forming a fourth film on the third film.

FIG. 7A is a TEM image of a surface of a wafer in an example including a first film and a second film on the surface. FIG. 7B is a TEM image of the surface of the wafer in an example after forming an initial layer and a third film on the first film and the second film. FIG. 7C is a TEM image of the surface of the wafer in the example after the surface of the wafer after forming the third film is exposed to an etching agent for 30 minutes. FIG. 7D is a TEM image of the surface of the wafer in the example after the surface of the wafer after forming the third film is exposed to an etching agent for 60 minutes. FIG. 7E is a TEM image of the surface of the wafer in the example after the surface of the wafer after forming the third film is exposed to an etching agent for 90 minutes. FIG. 7F is a TEM image of the surface of the wafer in the example after the surface of the wafer after forming the third film is exposed to an etching agent for 25 minutes and then a fourth film is formed on the third film. FIG. 7G is a TEM image of the surface of the wafer in the example after a fourth film is formed on the third film after forming multiple air gaps by removing portions of the first film while retaining the second film and the third film.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### <Embodiments of the Present Disclosure>

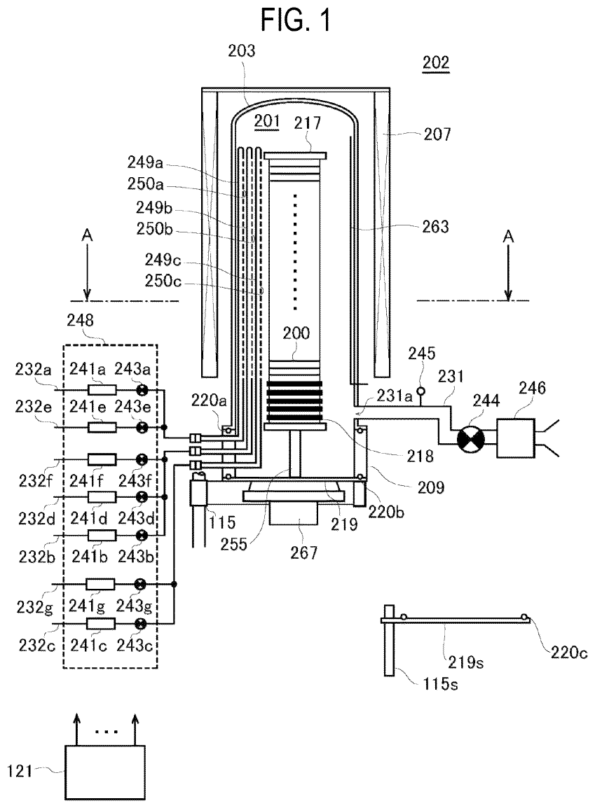

Hereinafter, some embodiments of the present disclosure will be described mainly with reference to FIGS. 1 to 4 and FIGS. 5A to 5E. Drawings used in the following description are schematic, and dimensional relationships, ratios, and the like of the respective components shown in the drawings may not match actual ones. Further, dimensional relationships, ratios, and the like of the respective components may not match among a plurality of drawings.

### (1) Configuration of Substrate Processing System (Substrate Processing Apparatus)

As shown in FIG. 1, a process furnace 202 includes a heater 207 as a heating mechanism (temperature regulating part). The heater 207 is formed in a cylindrical shape and is vertically installed by being supported by a holding plate. The heater 207 functions as an activator (an exciter) configured to activate (excite) a gas with heat.

A reaction tube 203 is disposed inside the heater 207 to be concentric with the heater 207. The reaction tube 203 is made of, for example, a heat resistant material such as quartz (SiO₂) or silicon carbide (SiC), and formed in a cylindrical shape with its upper end closed and its lower end opened. A manifold 209 is disposed to be concentric with the reaction tube 203 under the reaction tube 203. The manifold 209 is made of, for example, a metal material such as stainless steel (SUS), and is formed in a cylindrical shape with both of its upper and lower ends opened. The upper end of the manifold 209 engages with the lower end of the reaction tube 203 so as to support the reaction tube 203. An O-ring 220a serving as a seal is installed between the manifold 209 and the reaction tube 203. Similar to the heater 207, the reaction tube 203 is vertically installed. A process container (reaction container) mainly includes the reaction tube 203 and the manifold 209. A process chamber 201 is formed in a hollow cylindrical area of the process container. The process chamber 201 is configured to be capable of accommodating wafers 200 as substrates. Processing on the wafers 200 is performed in the process chamber 201.

Nozzles 249a to 249c as first to third suppliers are installed in the process chamber 201 so as to penetrate a sidewall of the manifold 209. The nozzles 249a to 249c are also referred to as first to third nozzles, respectively. The nozzles 249a to 249c are made of, for example, a heat resistant material such as quartz or SiC. Gas supply pipes 232a to 232c are connected to the nozzles 249a to 249c, respectively. The nozzles 249a to 249c are different nozzles, and each of the nozzles 249a and 249c is installed adjacent to the nozzle 249b.

Mass flow controllers (MFCs) 241a to 241c, which are flow rate controllers (flow rate control parts), and valves 243a to 243c, which are opening/closing valves, are installed at the gas supply pipes 232a to 232c, respectively, sequentially from the upstream side of a gas flow. A gas supply pipe 232e is connected to the gas supply pipe 232a at the downstream side of the valves 243a. Gas supply pipes 232d and 232f are connected to the gas supply pipe 232b at the downstream side of the valves 243b, respectively. A gas supply pipe 232g is connected to the gas supply pipe 232c at the downstream side of the valves 243c. MFCs 241d to 241g and valves 243d to 243g are installed at the gas supply pipes 232d to 232g, respectively, sequentially from the upstream side of a gas flow. The gas supply pipes 232a to 232g are made of, for example, a metal material such as SUS.

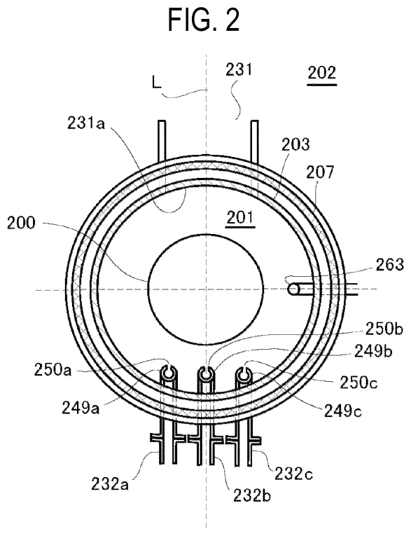

As shown in FIG. 2, each of the nozzles 249a to 249c is installed in an annular space (in a plane view) between an inner wall of the reaction tube 203 and the wafers 200 so as to extend upward from a lower side to an upper side of the inner wall of the reaction tube 203, that is, along an arrangement direction of the wafers 200. Specifically, each of the nozzles 249a to 249c is installed in a region horizontally surrounding a wafer arrangement region in which the wafers 200 are arranged at a lateral side of the wafer arrangement region, along the wafer arrangement region. In the plane view, the nozzle 249b is disposed so as to face an exhaust port 231a to be described later on a straight line with centers of the wafers 200 loaded into the process chamber 201 being interposed therebetween. The nozzles 249a and 249c are arranged so as to sandwich a straight line L passing through the nozzle 249b and the center of the exhaust port 231a from both sides along the inner wall of the reaction tube 203 (an outer periphery of the wafers 200). The straight line L is also a straight line passing through the nozzle 249b and the centers of the wafers 200. That is, it may be said that the nozzle 249c is installed on the side opposite to the nozzle 249a with the straight line L interposed therebetween. The nozzles 249a and 249c are arranged in line symmetry with the straight line L as the axis of symmetry. Gas supply holes 250a to 250c configured to supply a gas are formed on the side surfaces of the nozzles 249a to 249c, respectively. Each of the gas supply holes 250a to 250c is opened so as to oppose (face) the exhaust port 231a in the plane view, which enables a gas to be supplied toward the wafers 200. A plurality of gas supply holes 250a to 250c are formed from the lower side to the upper side of the reaction tube 203.

A precursor serving as a film-forming agent is supplied from the gas supply pipe 232a into the process chamber 201 via the MFC 241a, the valve 243a, and the nozzle 249a.

A first reactant serving as a film-forming agent is supplied from the gas supply pipe 232b into the process chamber 201 via the MFC 241b, the valve 243b, and the nozzle 249b.

A second reactant serving as a film-forming agent is supplied from the gas supply pipe 232c into the process chamber 201 via the MFC 241c, the valve 243c, and the nozzle 249c.

An etching agent is supplied from the gas supply pipe 232d into the process chamber 201 via the MFC 241d, the valve 243d, the gas supply pipe 232b, and the nozzle 249b.

An inert gas is supplied from the gas supply pipes 232e to 232g into the process chamber 201 via the MFCs 241e to 241g, the valves 243e to 243g, the gas supply pipes 232a to 232c, and the nozzles 249a to 249c, respectively. The inert gas acts as a purge gas, a carrier gas, a dilution gas, or the like.

A precursor supply system mainly includes the gas supply pipe 232a, the MFC 241a, and the valve 243a. A first reactant supply system mainly includes the gas supply pipe 232b, the MFC 241b, and the valve 243b. A second reactant supply system mainly includes the gas supply pipe 232c, the MFC 241c, and the valve 243c. An etching agent supply system (an etching agent exposure system) mainly includes the gas supply pipe 232d, the MFC 241d, and the valve 243d. An inert gas supply system mainly includes the gas supply pipes 232e to 232g, the MFCs 241e to 241g, and the valves 243e to 243g.

One or the entirety of the above-described various supply systems may be constituted as an integrated-type supply system 248 in which the valves 243a to 243g, the MFCs 241a to 241g, and so on are integrated. The integrated-type supply system 248 is connected to each of the gas supply pipes 232a to 232g. In addition, the integrated-type supply system 248 is configured such that operations of supplying various materials (various gases) into the gas supply pipes 232a to 232g (that is, opening/closing operations of the valves 243a to 243g, flow rate regulating operations by the MFCs 241a to 241g, and the like) are controlled by a controller 121 which will be described later. The integrated-type supply system 248 is constituted as an integral-type or detachable-type integrated unit, and may be attached to or detached from the gas supply pipes 232a to 232g and the like on an integrated unit basis, such that maintenance, replacement, extension, etc. of the integrated-type supply system 248 may be performed on an integrated unit basis.

The exhaust port 231a configured to exhaust an internal atmosphere of the process chamber 201 is installed below the sidewall of the reaction tube 203. As shown in FIG. 2, in the plane view, the exhaust port 231a is installed at a position opposing (facing) the nozzles 249a to 249c (the gas supply holes 250a to 250c) with the wafers 200 interposed therebetween. The exhaust port 231a may be installed from the lower side to the upper side of the sidewall of the reaction tube 203, that is, along the wafer arrangement region. An exhaust pipe 231 is connected to the exhaust port 231a. A vacuum pump 246 as a vacuum exhauster, is connected to the exhaust pipe 231 via a pressure sensor 245, which is a pressure detector (pressure detection part) configured to detect an internal pressure of the process chamber 201, and an auto pressure controller (APC) valve 244, which is a pressure regulator (pressure regulating part). The APC valve 244 is configured to be capable of performing or stopping a vacuum exhausting operation in the process chamber 201 by opening or closing the valve while the vacuum pump 246 is actuated, and is also configured to be capable of regulating the internal pressure of the process chamber 201 by adjusting a degree of valve opening based on pressure information detected by the pressure sensor 245 while the vacuum pump 246 is actuated. An exhaust system mainly includes the exhaust pipe 231, the APC valve 244, and the pressure sensor 245. The exhaust system may include the vacuum pump 246.

A seal cap 219 as a furnace opening lid configured to be capable of airtightly closing a lower end opening of the manifold 209 is installed below the manifold 209. The seal cap 219 is made of, for example, metal material such as SUS, and is formed in a disc shape. An O-ring 220b as a seal, which comes into contact with the lower end of the manifold 209, is installed on an upper surface of the seal cap 219. A rotator 267 configured to rotate a boat 217 to be described below is installed below the seal cap 219. A rotary shaft 255 of the rotator 267 is connected to the boat 217 through the seal cap 219. The rotator 267 is configured to rotate the wafers 200 by rotating the boat 217. The seal cap 219 is configured to be vertically moved up or down by a boat elevator 115 which is an elevator installed outside the reaction tube 203. The boat elevator 115 is constituted as a transfer apparatus (transfer mechanism) configured to load or unload (transfer) the wafers 200 into or out of the process chamber 201 by moving the seal cap 219 up or down.

Below the manifold 209, a shutter 219s is installed as a furnace opening lid configured to be capable of airtightly closing the lower end opening of the manifold 209 while the seal cap 219 is lowered and the boat 217 is unloaded from the process chamber 201. The shutter 219s is made of, for example, metal material such as SUS, and is formed in a disc shape. An O-ring 220c as a seal, which comes into contact with the lower end of the manifold 209, is installed on an upper surface of the shutter 219s. The opening/closing operation (such as elevation operation, rotation operation, or the like) of the shutter 219s is controlled by a shutter opening/closing mechanism 115s.

The boat 217 serving as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with one another. That is, the boat 217 is configured to arrange the wafers 200 to be spaced apart from each other. The boat 217 is made of, for example, heat resistant material such as quartz or SiC. Heat insulating plates 218 made of, for example, heat resistant material such as quartz or SiC are installed in multiple stages at the bottom of the boat 217.

A temperature sensor 263 serving as a temperature detector is installed in the reaction tube 203. Based on temperature information detected by the temperature sensor 263, a state of supplying electric power to the heater 207 is regulated such that a temperature distribution in the process chamber 201 becomes a desired temperature distribution. The temperature sensor 263 is installed along the inner wall of the reaction tube 203.

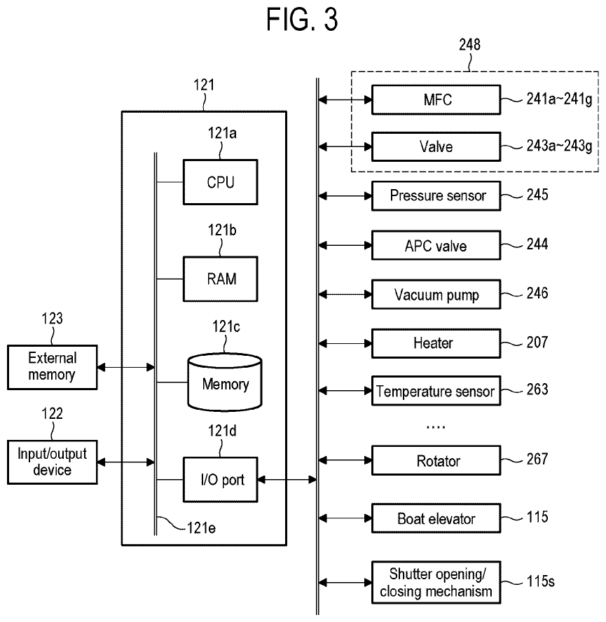

As shown in FIG. 3, the controller 121 as a control part (control means or unit) is constituted as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 constituted as, for example, a touch panel or the like is connected to the controller 121. Further, an external memory 123 may be connected to the controller 121.

The memory 121c includes, for example, a flash memory, a hard disk drive (HDD), a solid state drive (SSD), or the like. A control program that controls operations of a substrate processing apparatus, a process recipe in which sequences and conditions of substrate processing to be described below are written, and the like are readably recorded and stored in the memory 121c. The process recipe functions as a program that is combined to cause, by the controller 121, the substrate processing apparatus to perform each sequence in the substrate processing (film-forming processing) to be described below to obtain an expected result. Hereinafter, the process recipe and the control program may be generally and simply referred to as a “program.” Further, the process recipe may be simply referred to as a “recipe.” When the term “program” is used herein, it may indicate a case of including the recipe, a case of including the control program, or a case of including both the recipe and the control program. The RAM 121b is constituted as a memory area (work area) in which programs or data read by the CPU 121a are temporarily stored.

The I/O port 121d is connected to the MFCs 241a to 241g, the valves 243a to 243g, the pressure sensor 245, the APC valve 244, the vacuum pump 246, the temperature sensor 263, the heater 207, the rotator 267, the boat elevator 115, the shutter opening/closing mechanism 115s, the RPU 300, and the like.

The CPU 121a is configured to be capable of reading and executing the control program from the memory 121c. The CPU 121a is also configured to be capable of reading the recipe from the memory 121c according to an input of an operation command from the input/output device 122, or the like. The CPU 121a is configured to be capable of controlling the flow rate regulating operation of various kinds of materials (gases) by the MFCs 241a to 241g, the opening/closing operation of the valves 243a to 243g, the opening/closing operation of the APC valve 244, the pressure regulating operation performed by the APC valve 244 based on the pressure sensor 245, the actuating and stopping operation of the vacuum pump 246, the temperature regulating operation performed by the heater 207 based on the temperature sensor 263, the operation of rotating the boat 217 and adjusting the rotation speed of the boat 217 with the rotator 267, the operation of moving the boat 217 up or down by the boat elevator 115, the opening/closing operation of the shutter 219s by the shutter opening/closing mechanism 115s, and so on, according to contents of the read recipe.

The controller 121 may be constituted by installing, in the computer, the above-described program recorded and stored in the external memory 123. Examples of the external memory 123 may include a magnetic disc such as a HDD, an optical disc such as a CD, a magneto-optical disc such as a MO, a semiconductor memory such as a USB memory or a SSD, and the like. The memory 121c or the external memory 123 is constituted as a computer-readable recording medium. Hereinafter, the memory 121c and the external memory 123 may be generally and simply referred to as a “recording medium.” When the term “recording medium” is used herein, it may indicate a case of including the memory 121c, a case of including the external memory 123, or a case of including both the memory 121c and the external memory 123. Furthermore, the program may be provided to the computer by using communication means or unit such as the Internet or a dedicated line, instead of using the external memory 123.

### (2) Substrate Processing Process

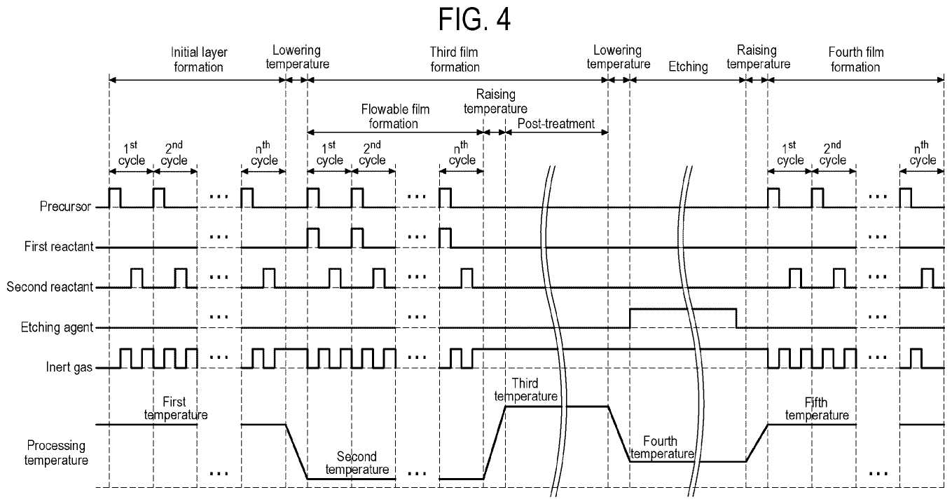

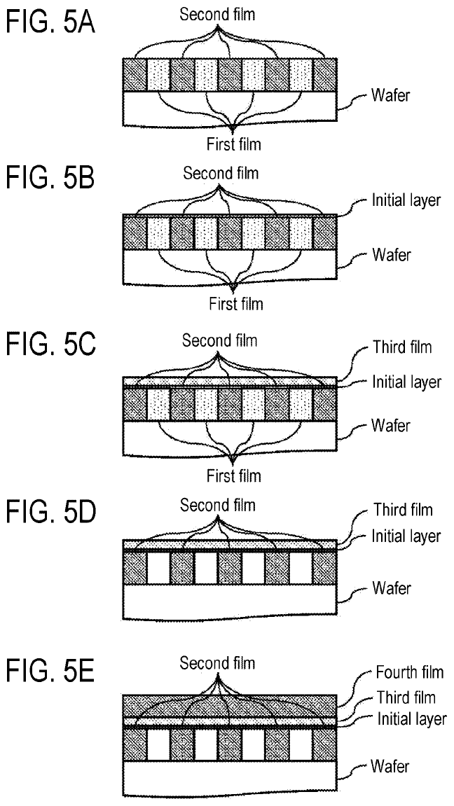

An example of a method of processing a substrate, i.e., a processing sequence to form an air gap on a wafer 200 as the substrate, will be described as a process of manufacturing a semiconductor device by using the above-described substrate processing system (substrate processing apparatus) mainly with reference to FIG. 4 and FIGS. 5A to 5E. In the following description, an operation of each component of the substrate processing apparatus is controlled by the controller 121.

The wafer 200 includes a first film and a second film on the surface thereof. In the following, an example will be described in which the first film is a film (first base) containing a semiconductor element and oxygen, and the second film is a film (second base) containing a semiconductor element and nitrogen or a metal element. Further, in the following, as a representative example, a case will be described in which the first film is a silicon oxide film (SiO₂ film, hereinafter also referred to as a SiO film) containing silicon (Si) as the semiconductor element and oxygen (O), and the second film is a silicon nitride film (Si₃N₄ film, hereinafter also referred to as a SiN film) containing silicon (Si) as the semiconductor element and nitrogen (N).

The processing sequence according to the embodiments of the present disclosure includes:
(a) a step of forming a third film on a first film and a second film formed on a surface of a wafer 200 by supplying a precursor, a first reactant, and a second reactant to the wafer 200 under a condition in which thermal decomposition of the precursor does not occur and physical adsorption of the precursor occurs more predominantly than chemical adsorption of the precursor when the precursor is present alone (third film formation); and
(b) a step of removing the first film while retaining the second film and the third film by exposing the surface of the wafer 200 where the third film is formed on the first film and the second film to an etching agent that reacts with the first film (etching).

In the processing sequence according to the embodiments of the present disclosure, before performing the third film formation, a step of forming an initial layer on the first film and the second film by supplying the precursor, the first reactant or the second reactant under a condition in which the chemical adsorption or the thermal decomposition of the precursor occurs more predominantly than the physical adsorption of the precursor when the precursor is present alone (initial layer formation) is performed. That is, in the embodiments of the present disclosure, the initial layer is formed on the first film and the second film, and the third film is formed on the initial layer. Depending on the materials of the first film and the second film, the formation of the initial layer may be omitted. When the formation of the initial layer is omitted, the third film is formed directly on the first film and the second film.

Further, the processing sequence according to the embodiments of the present disclosure includes, after performing the etching:
(c) a step of forming a non-flowable film as a fourth film on the third film (fourth film formation).

Each of these steps is performed in a non-plasma atmosphere.

In the following, as a representative example, a case will be described in which as shown in FIG. 4, in the initial layer formation, a cycle including step A1 of supplying the precursor to the wafer 200 and step A2 of supplying the first reactant or the second reactant to the wafer 200 is performed a predetermined number of times (n₁ times where n₁ is an integer of 1 or 2 or more) at a first temperature. FIG. 4 shows a case where the second reactant is supplied to the wafer 200 in step A2.

Further, in the following, as a representative example, a case will be described in which as shown in FIG. 4, the third film formation includes:
a step of forming a film with fluidity (hereinafter also referred to as a flowable film) on the initial layer by performing a cycle including step B1 of simultaneously supplying the precursor and the first reactant to the wafer 200 and step B2 of supplying the second reactant to the wafer 200 a predetermined number of times (n₂ times where n₂ is an integer of 1 or 2 or more) at a second temperature lower than the first temperature (flowable film formation); and
a step of heat-treating the wafer 200 on which the flowable film is formed at a third temperature higher than the second temperature to modify the flowable film into a film with no fluidity (hereinafter also referred to as a non-flowable film) (post-treatment). In the present disclosure, the post-treatment is also referred to as PT.

Further, in the following, as a representative example, a case will be described in which as shown in FIG. 4, the fourth film formation includes performing a cycle including step C1 of supplying the precursor to the wafer 200 and step C2 of supplying the first reactant or the second reactant to the wafer 200 a predetermined number of times (n₃ times where n₃ is an integer of 1 or 2 or more) at a third temperature higher than the second temperature. FIG. 4 shows that the second reactant is supplied to the wafer 200 in step C2

In present disclosure, for the sake of convenience, the processing sequence shown in FIG. 4 may be denoted as follows. The same notation will be used in the following descriptions of modifications and other embodiments.

(precursor→second reactant)×n₁ Initial layer formation:

(precursor+first reactant→second reactant)×n₂→PT Third film formation:

(precursor→second reactant)×n₃ Fourth film formation:

As in the processing sequence shown below, in the formation of the flowable film in the third film formation, timings of supplying the precursor, the first reactant, and the second reactant may be appropriately changed.

(precursor→first reactant→second reactant)×n₂→PT Third film formation:

(precursor→first reactant→second reactant→first reactant)×n₂→PT Third film formation:

(precursor+first reactant→second reactant→first reactant)×n₂→PT Third film formation:

The term “wafer” used herein may refer to a wafer itself or a stacked body of a wafer and a predetermined layer or film formed on a surface of the wafer. The phrase “a surface of a wafer” used herein may refer to a surface of a wafer itself or a surface of a predetermined layer or the like formed on a wafer. The expression “a predetermined layer is formed on a wafer” used herein may mean that a predetermined layer is directly formed on a surface of a wafer itself or that a predetermined layer is formed on a layer or the like formed on a wafer. The term “substrate” used herein may be synonymous with the term “wafer.”

As used herein, the term such as “agent” includes at least one selected from the group of a gaseous substance and a liquid substance. The liquid substance includes a mist-like substance. That is, each of the film-forming agents (the precursor, the first reactant, and the second reactant) and the etching agent may include a gaseous substance, a liquid substance such as a mist-like substance, or both of them.

As used herein, the term “layer” includes at least one selected from the group of a continuous layer and a discontinuous layer. A layer formed in each step to be described later may include a continuous layer, a discontinuous layer, or both of them.

### (Wafer Charging and Boat Loading)

After the boat 217 is charged with a plurality of wafers 200 (wafer charging), the shutter 219s is moved by the shutter opening/closing mechanism 115s and the lower end opening of the manifold 209 is opened (shutter opening). Thereafter, as shown in FIG. 1, the boat 217 supporting the plurality of wafers 200 is lifted by the boat elevator 115 and loaded into the process chamber 201 (boat loading). In this state, the seal cap 219 seals the lower end of the manifold 209 via the O-ring 220b. Thus, the wafers 200 are provided inside the process chamber 201.

On the surface of the wafer 200 charged in the boat 217, i.e., on the surface of the wafer 200 before the formation of the initial layer and the third film, the first film and the second film are alternately arranged so as to be adjacent to each other, as shown in FIG. 5A. Herein, a case will be described in which the first film and the second film are alternately arranged on the flat surface of the wafer 200 parallel to the flat surface. Further, herein, a case will be described in which the first film is a SiO film and the second film is a SiN film, as described above.

### (Pressure Regulation and Temperature Regulation)

After the boat loading is completed, the inside of the process chamber 201, that is, a space where the wafers 200 are placed, is vacuum-exhausted (decompression-exhausted) by the vacuum pump 246 to reach a desired pressure (state of vacuum). In this operation, the internal pressure of the process chamber 201 is measured by the pressure sensor 245, and the APC valve 244 is feedback-controlled based on the measured pressure information (pressure regulation). Further, the wafers 200 in the process chamber 201 are heated by the heater 207 to reach a desired processing temperature. In this operation, a state of supplying electric power to the heater 207 is feedback-controlled based on the temperature information detected by the temperature sensor 263 such that a temperature distribution in the process chamber 201 becomes a desired temperature distribution (temperature regulation). Further, the rotation of the wafers 200 by the rotator 267 is started. The exhaust of the inside of the process chamber 201 and the heating and rotation of the wafers 200 may be continuously performed at least until the processing on the wafers 200 is completed.

### (Initial Layer Formation)

In the initial layer formation, the following steps A1 and A2 are performed.

### [Step A1]

In step A1, the precursor is supplied to the wafers 200 in the process chamber 201.

Specifically, the valve 243a is opened to allow the precursor to flow through the gas supply pipe 232a. A flow rate of the precursor is regulated by the MFC 241a. The precursor is supplied into the process chamber 201 via the nozzle 249a, and exhausted via the exhaust port 231a. At this time, the precursor is supplied to the wafers 200 (supply of precursor). At this time, the valves 243e to 243g may be opened to supply an inert gas into the process chamber 201 via each of the nozzles 249a to 249c.

After a predetermined time elapses, the valve 243a is closed to stop the supply of the precursor into the process chamber 201. Then, the inside of the process chamber 201 is vacuum-exhausted to remove gaseous substances remaining in the process chamber 201 from the inside of the process chamber 201. At this time, the valves 243e to 243g are opened to supply an inert gas into the process chamber 201 via the nozzles 249a to 249c. The inert gas supplied from the nozzles 249a to 249c acts as a purge gas, thereby purging the space in which the wafers 200 exist, i.e., the inside of the process chamber 201 (purging).

As the precursor, for example, a silane-based gas containing silicon (Si) may be used. As the silane-based gas, for example, a gas containing Si and a halogen, i.e., a halosilane-based gas may be used. The halogen includes chlorine (Cl), fluorine (F), bromine (Br), iodine (I), and the like. That is, the halosilane-based gas includes a chlorosilane-based gas, a fluorosilane-based gas, a bromosilane-based gas, an iodosilane-based gas, and the like. As the halosilane-based gas, for example, a gas containing silicon, carbon (C), and a halogen, i.e., an organic halosilane-based gas may be used. As the organic halosilane-based gas, for example, a gas containing Si, C, and Cl, i.e., an organic chlorosilane-based gas may be used.

Examples of the precursor may include C- and halogen-free silane-based gases such as a monosilane (SiH₄) gas and a disilane (Si₂H₆) gas, C-free halosilane-based gases such as a dichlorosilane (SiH₂Cl₂) gas and a hexachlorodisilane (Si₂Cl₆) gas, alkylsilane-based gases such as a trimethylsilane (SiH(CH₃)₃) gas, a dimethylsilane (SiH₂(CH₃)₂) gas, a triethylsilane (SiH(C₂H₅)₃) gas and a diethylsilane (SiH₂(C₂H₅)₂) gas, alkylenehalosilane-based gases such as a bis(trichlorosilyl) methane ((SiCl₃)₂CH₂) gas and a 1,2-bis(trichlorosilyl) ethane ((SiCl₃)₂C₂H₄) gas, and alkylhalosilane-based gases such as trimethylchlorosilane (SiCl(CH₃)₃) gas, a dimethyldichlorosilane (SiCl₂(CH₃)₂) gas, a triethylchlorosilane (SiCl(C₂H₅)₃) gas, a diethyldichlorosilane (SiCl₂(C₂H₅)₂) gas, a 1,1,2,2-tetrachloro-1,2-dimethyldisilane ((CH₃)₂Si₂Cl₄) gas and a 1,2-dichloro-1,1,2,2-tetramethyldisilane ((CH₃)₄Si₂Cl₂) gas. Further, examples of the precursor may include alkylaminosilane-based gases such as a (dimethylamino)trimethylsilane ((CH₃)₂NSi(CH₃)₃) gas, a (diethylamino)triethylsilane ((C₂H₅)₂NSi(C₂H₅)₃) gas, a (dimethylamino)triethylsilane ((CH₃)₂NSi(C₂H₅)₃) gas, a (diethylamino)trimethylsilane ((C₂H₅)₂NSi(CH₃)₃) gas, a (trimethylsilyl)amine ((CH₃)₃SiNH₂) gas, a (triethylsilyl)amine ((C₂H₅)₃SiNH₂) gas, a (dimethylamino) silane ((CH₃)₂NSiH₃) gas and a (diethylamino) silane ((C₂H₅)₂NSiH₃) gas. As the precursor, one or more of these silicon-containing precursors may be used.

Some of these precursors do not contain an amino group but contain a halogen. Further, some of these precursors contain a chemical bond between silicon and silicon (a Si-Si bond). Further, some of these precursors contain silicon and halogen, or contain silicon, halogen, and carbon. Further, some of these precursors contain an alkyl group and halogen. That is, some of these precursors contain a halogeno group and an alkyl group.

As the inert gas, a nitrogen (N₂) gas, or a rare gas such as an argon (Ar) gas, a helium (He) gas, a neon (Ne) gas, a xenon (Xe) gas, or the like may be used. The same applies to each step to be described later. As the inert gas, one or more of these gases may be used.

### [Step A2]

In step A2, the first reactant or the second reactant is supplied to the wafers 200 in the process chamber 201.

When the first reactant is supplied to the wafers 200, the valve 243b is opened to allow the first reactant to flow through the gas supply pipe 232b. A flow rate of the first reactant is regulated by the MFC 241b. The first reactant is supplied into the process chamber 201 via the nozzle 249b and exhausted via the exhaust port 231a. At this time, the first reactant is supplied to the wafers 200 (supply of first reactant). At this time, the valves 243e to 243g may be opened to supply an inert gas into the process chamber 201 via each of the nozzles 249a to 249c.

Further, when the second reactant is supplied to the wafers 200 as shown in FIG. 4, the valve 243c is opened to allow the second reactant to flow through the gas supply pipe 232c. A flow rate of the second reactant is regulated by the MFC 241c. The second reactant is supplied into the process chamber 201 via the nozzle 249c and exhausted via the exhaust port 231a. At this time, the second reactant is supplied to the wafers 200 (supply of second reactant). At this time, the valves 243e to 243g may be opened to supply an inert gas into the process chamber 201 via each of the nozzles 249a to 249c.

After a predetermined time elapses, the valve 243b or 243c is closed to stop the supply of the first reactant or the second reactant into the process chamber 201. Then, gaseous substances remaining in the process chamber 201 are removed from the inside of the process chamber 201 by the same processing procedure as the purging in step A1.

As the first reactant and the second reactant, for example, a nitrogen (N)- and hydrogen (H)-containing gas may be used. The first reactant and the second reactant may contain the same molecular structure or may contain different molecular structures. Examples of the N- and H-containing gas may include hydrogen nitride gases such as an ammonia (NH₃) gas and the like, ethylamine-based gases such as a monoethylamine (C₂H₅NH₂) gas, a diethylamine ((C₂H₅)₂NH) gas and a triethylamine ((C₂H₅)₃N) gas, methylamine-based gases such as a monomethylamine (CH₃NH₂) gas, a dimethylamine ((CH₃)₂NH) gas, and a trimethylamine ((CH₃)₃N) gas, cyclic amine-based gases such as a pyridine (C₅H₅N) gas and a piperazine (C₄H₁₀N₂) gas, and organic hydrazine-based gases such as a monomethylhydrazine ((CH₃)HN₂H₂) gas, a dimethylhydrazine ((CH₃)₂N₂H₂) gas and a trimethylhydrazine ((CH₃)₂N₂(CH₃)H) gas. Since the amine-based gases and the organic hydrazine-based gases are constituted by C, N, and H, these gases may also be referred to as C-, N-, and H-containing gases. The amine-based gas containing the above-mentioned alkyl group may also be referred to as an alkylamine-based gas. Instead of the C-, N-, and H-containing gases, a C-containing gas (a C- and H-containing gas) such as an ethylene (C₂H₄) gas, an acetylene (C₂H₂) gas or a propylene (C₃H₆) gas, and a N-containing gas (a N- and H-containing gas) such as a NH₃ gas may be supplied simultaneously or non-simultaneously. As the first reactant and the second reactant, one or more selected from the group of these N- and H-containing reactants or C-, N-, and H-containing reactants may be used. The first reactant may contain an alkyl group, or may contain an amine or an organic hydrazine.

### [Performing Predetermined Number of Times]

A cycle including the above-mentioned steps A1 and A2, i.e., a cycle in which A1 and A2 are performed non-simultaneously, is performed a predetermined number of times (n₁ times where n₁ is an integer of 1 or 2 or more). At this time, when the precursor is present alone, the above-mentioned cycle is performed a predetermined number of times under a condition in which chemical adsorption or thermal decomposition of the precursor occurs more predominantly than physical adsorption of the precursor.

Processing conditions when supplying the precursor in step A1 are exemplified as follows:
Processing temperature (first temperature): 350 to 700 degrees C., more specifically 450 to 650 degrees C.
Processing pressure: 1 to 2,666 Pa, specifically 67 to 1,333 Pa
Supply flow rate of precursor: 0.001 to 2 slm, specifically 0.01 to 1 slm
Supply time of precursor: 1 to 120 seconds, specifically 1 to 60 seconds
Supply flow rate of inert gas (for each gas supply pipe): 0 to 20 slm, specifically 0.01 to 10 slm

In the present disclosure, when a numerical range such as “350 to 700 degrees C.” is indicated, it means that a lower limit and an upper limit are included in the range. Thus, for example, “350 to 700 degrees C.” means “350 degrees C. or higher and 700 degrees C. or lower.” The same applies to other numerical ranges. In the present disclosure, a processing temperature means a temperature of the wafers 200 or an internal temperature of the process chamber 201, and a process pressure means an internal pressure of the process chamber 201. Further, when a supply flow rate of gas of 0 slm means that the gas is not supplied. The same applies to the following descriptions.

Processing conditions when supplying the first reactant or the second reactant in step A2 are exemplified as follows:
Processing pressure: 1 to 4,000 Pa, specifically 1 to 3,000 Pa
Supply flow rate of first reactant or second reactant: 0.001 to 20 slm, specifically 1 to 10 slm
Supply time of first reactant or second reactant: 1 to 120 seconds, specifically 1 to 60 seconds

Other processing conditions may be the same as the processing conditions used when supplying the precursor in step A1.

By supplying the precursor in step A1 under the above-mentioned processing conditions, a portion of a molecular structure of a molecule of the precursor may be adsorbed on the surface of the wafer 200, i.e., the surfaces of the first film and the second film, in step A1. Further, by supplying the first reactant or the second reactant in step A2 under the above-mentioned processing conditions, a portion of the molecular structure of the molecule of the precursor adsorbed on the surfaces of the first film and the second film may be caused to react with the first reactant or the second reactant so as to be modified, which makes it possible to form a layer with no fluidity (hereinafter also referred to as a non-flowable layer). Then, by performing the above-mentioned cycle a predetermined number of times under the above-mentioned processing conditions, a non-flowable layer of a predetermined thickness may be formed as an initial layer on the first film and the second film, as shown in FIG. 5B. The initial layer becomes a continuous layer that conformally covers the surfaces of the first film and the second film.

The above-described cycle may be performed a plurality of times. That is, a thickness of the non-flowable layer formed per cycle may set to be smaller than a desired thickness, and the above-described cycle may be performed a plurality of times until a thickness of the initial layer formed by stacking the non-flowable layers reaches the desired thickness. The thickness of the initial layer may be equal to or smaller than a thickness of a flowable film to be described later, or smaller than the thickness of the flowable film. The thickness of the initial layer may be, for example, 0.2 nm or more and 5 nm or less, specifically 0.3 nm or more and 3 nm or less.

When the various precursors and the various reactants exemplified above are used, a Si- and N-containing layer such as a silicon nitride layer (a SiN layer), or a Si-, C- and N-containing layer such as a silicon carbonitride layer (a SiCN layer) may be formed as the initial layer. Since the above-mentioned various precursors and reactants do not contain oxygen (O), the initial layer is an O-free layer. The initial layer is a layer that is less hydrophilic than the first film (O-containing film) formed on the surface of the wafer 200. When the first film, which is a portion of the base for film formation, is a hydrophilic film, the initial layer may be a non-hydrophilic layer (hydrophobic layer).

### (Third Film Formation)

After the initial layer is formed on the first film and the second film, the third film is formed. In the third film formation, the following two steps, i.e., flowable film formation and post treatment are performed.

### [Flowable Film Formation]

When forming the flowable film, an output of the heater 207 is regulated such that the temperature of the wafer 200 is changed to a second temperature lower than the first temperature described above (temperature reduction). Then, in a state where the temperature of the wafer 200 reaches the second temperature to be stabilized, the following steps B1 and B2 are performed.

### [Step B1]

In step B1, the precursor and the first reactant are simultaneously supplied to the wafer 200 in the process chamber 201. Processing procedures when supplying the precursor and processing procedures when supplying the first reactant may be the same as the processing procedures in steps A1 and A2 described above, respectively.

After a predetermined time elapses, the valves 243a and 243b are closed to stop the supply of the precursor and the first reactant into the process chamber 201. Then, gaseous substances remaining in the process chamber 201 are removed from the inside of the process chamber 201 by the same processing procedure as the purging in step A1.

As the precursor, a predetermined precursor may be arbitrarily selected from the various precursors exemplified in step A1. The precursor used in step B1 and the precursor used in step A1 may contain the same molecular structure or may contain different molecular structures.

As the first reactant, a predetermined reactant may be arbitrarily selected from the various reactants exemplified in step A2. The reactant used in step B1 and the reactant used in step A2 may contain the same molecular structure or different molecular structures.

### [Step B2]

In step B2, the second reactant is supplied to the wafer 200 in the process chamber 201. Processing procedure when supplying the second reactant may be the same as the processing procedure in step A2 described above.

After a predetermined time elapses, the valve 243c is closed to stop the supply of the second reactant into the process chamber 201. Then, gases remaining in the process chamber 201 are removed from the inside of the process chamber 201 by the same processing procedure as the purging in step A1.

As the second reactant, a predetermined reactant may be arbitrarily selected from the various reactants exemplified in step A2. The reactant used in step B2 and the reactant used in steps A1 and B1 may contain the same molecular structure or different molecular structures.

### [Performed Predetermined Number of Times]

A cycle including the above-mentioned steps B1 and B2, i.e., a cycle in which B1 and B2 are performed non-simultaneously, is performed a predetermined number of times (n₂ times where n₂ is an integer of 1 or 2 or more). At this time, when the precursor is present alone, the above-mentioned cycle is performed a predetermined number of times under a condition in which thermal decomposition of the precursor does not occur and the physical adsorption of the precursor occurs more predominantly than the chemical adsorption of the precursor.

Processing conditions when supplying the precursor and the first reactant in step B1 are exemplified as follows:
Processing temperature (second temperature): 0 to 150 degrees C., specifically 10 to 100 degrees C., more specifically 20 to 60 degrees C.
Processing pressure: 10 to 6,000 Pa, specifically 50 to 2,000 Pa
Supply flow rate of precursor: 0.01 to 1 slm
Supply flow rate of first reactant: 0.01 to 5 slm
Supply time of precursor and first reactant: 1 to 300 seconds
Supply flow rate of inert gas (for each gas supply pipe): 0 to 20 slm, specifically 0.01 to 10 slm.

Processing conditions when supplying the second reactant in step B2 are exemplified as follows:
Supply flow rate of second reactant: 0.001 to 5 slm
Supply time of second reactant: 1 to 300 seconds.

Other processing conditions may be the same as the processing conditions used when supplying the precursor and the first reactant in step B1.

By performing the above-mentioned cycle a predetermined number of times under the above-mentioned processing conditions, an oligomer containing elements contained in at least one selected from the group of the precursor, the first reactant, and the second reactant may be generated, caused to grow, and caused to flow on the first and second films, i.e., on the initial layer formed on the first and second films, and a continuous oligomer-containing film may be formed as a flowable film on the initial layer. The oligomer refers to a polymer with a relatively low molecular weight (e.g., a molecular weight of 10,000 or less) to which a relatively small number of monomers (e.g., 10 to 100 monomers) are bonded. When the precursor, the first reactant, and the second reactant exemplified above are used, the flowable film becomes a film containing various elements such as Si, Cl, and N, and substances represented by a chemical formula CₓH₂ₓ₊₁ (where x is an integer of 1 to 3), such as CH₃ and C₂H₅.

Further, by performing the cycle including steps B1 and B2 under the above-mentioned processing conditions, it is possible to, while promoting growth and flow of the oligomer formed on the first film and the second film, remove and discharge excess components contained in a surface layer or an inside of the oligomer, such as excess gases, impurities containing Cl, and reaction by-products (hereinafter simply referred to as by-products).

In a case where the above-mentioned processing temperature is set to less than 0 degrees C., the precursor supplied into the process chamber 201 is likely to liquefy, which may make it difficult to supply the precursor in a gaseous state to the wafer 200. In this case, the reaction to form the above-mentioned flowable film may not proceed easily, which may make it difficult to form a flowable film on the initial layer. This issue may be resolved by setting the processing temperature to 0 degrees C. or higher. This issue may be sufficiently resolved by setting the processing temperature to 10 degrees C. or higher, and may be more sufficiently resolved by setting the processing temperature to 20 degrees C. or higher.

Further, in a case where the processing temperature is higher than 150 degrees C., the reaction to form the above-mentioned flowable film may not proceed easily. In this case, desorption of the oligomer generated on the initial layer may occur more predominantly than growth of the oligomer, which may make it difficult to form a flowable film on the initial layer. This issue may be resolved by setting the processing temperature to 150 degrees C. or less. This issue may be sufficiently resolved by setting the processing temperature to 100 degrees C. or less, and may be more sufficiently resolved by setting the processing temperature to 60 degrees C. or less.

For these reasons, the processing temperature may be set to 0 degrees C. or higher and 150 degrees C. or lower, specifically 10 degrees C. or higher and 100 degrees C. or lower, and more specifically 20 degrees C. or higher and 60 degrees C. or lower.

### [Post Treatment]

After the flowable film is formed on the first and second films, i.e., on the initial layer formed on the first and second films, the output of the heater 207 is regulated so as to change the temperature of the wafers 200 to a third temperature equal to or higher than the second temperature described above, specifically to a third temperature higher than the second temperature described above (raising temperature). Then, when the temperature of the wafers 200 reaches the third temperature to be stabilized, post treatment (PT) is performed.

In the PT, an inert gas is supplied to the wafers 200 in the process chamber 201. Specifically, the valves 243e to 243g are opened to allow the inert gas to flow through the gas supply pipes 232e to 232g. A flow rate of the inert gas is regulated by the MFCs 241e to 241g. The inert gas is supplied into the process chamber 201 via the nozzles 249a to 249c, and is exhausted via the exhaust port 231a. At this time, the inert gas is supplied to the wafers 200.

Processing conditions in the PT are exemplified as follows:
Processing temperature (third temperature): 100 to 1000 degrees C., specifically 200 to 600 degrees C.
Processing pressure: 10 to 80,000 Pa, specifically 200 to 6,000 Pa supply flow rate of inert gas (for each gas supply pipe): 0.01 to 2 slm
Supply time of inert gas: 300 to 10,800 seconds.

By performing the PT under the above-mentioned processing conditions, it is possible to modify the flowable film, which is a continuous oligomer-containing film formed on the initial layer. As a result, a Si-, C-, and N-containing film such as a SiCN film or a Si- and N-containing film such as a SiN film may be formed as the third film on the initial layer. The third film becomes a continuous film that conformally covers the surfaces of the first film and the second film, i.e., the surface of the initial layer formed on the first film and the second film. The third film is a flowable film at least during its formation process, but is changed to a non-flowable film by performing the PT. In the present disclosure, the term “third film” may include a film obtained by changing a flowable film to a non-flowable film by performing the PT, a flowable film before performing the PT, or both. A thickness of the third film formed through the flowable film formation and the PT may be, for example, 0.2 nm to 20 nm, specifically 0.5 nm to 10 nm.

By performing the PT, it is possible to discharge excess components contained in the flowable film and appropriately densify the third film. In addition, by setting the processing temperature (the third temperature) in the PT to a temperature higher than the processing temperature (the first temperature) when forming the initial layer, it is possible to modify the flowable film and modify the initial layer that is the base thereof. In other words, it is possible to discharge excess components contained in the initial layer and appropriately densify the initial layer. As a result, it is also possible to increase a hardness of the third film or the initial layer.

In the PT, a H-containing gas such as a hydrogen (H₂) gas may be supplied to the wafers 200, a N-containing gas such as a NH₃ gas, i.e., a N- and H-containing gas may be supplied to the wafers 200, or an O-containing gas such as a H₂O gas, i.e., an O- and H-containing gas may be supplied to the wafers 200. An O₂ gas may be supplied as the O-containing gas. In other words, in the PT, at least one selected from the group of a N-containing gas, a H-containing gas, a N- and H-containing gas, an O-containing gas, and an O- and H-containing gas may be supplied to the wafers 200.

Processing conditions when supplying the H-containing gas in the PT are exemplified as follows:
Supply flow rate of H-containing gas: 0.01 to 3 slm
Processing pressure: 10 to 1,000 Pa, specifically 200 to 800 Pa.

Other processing conditions may be the same as the processing conditions used when the PT is performed under an inert gas atmosphere.

Processing conditions when supplying the N- and H-containing gas in the PT are exemplified as follows:
Supply flow rate of N- and H-containing gas: 10 to 10,000 sccm
Processing pressure: 10 to 6,000 Pa, specifically 200 to 2,000 Pa.

Other processing conditions may be the same as the processing conditions used when the PT is performed under an inert gas atmosphere.

Processing conditions when supplying the O-containing gas in the PT are exemplified as follows:
Supply flow rate of O-containing gas: 10 to 10,000 sccm
Processing pressure: 10 to 90,000 Pa, specifically 20,000 to 80,000 Pa

Other processing conditions may be the same as the processing conditions used when the PT is performed under an inert gas atmosphere.

When the PT is performed under a H-containing gas atmosphere or a N- and H-containing gas atmosphere, it is possible to increase fluidity of the oligomer-containing layer, reduce an impurity concentration of the third film, increase a film density, and improve an etching resistance, compared to when the PT is performed under an inert gas atmosphere. When the PT is performed under the N- and H-containing gas atmosphere, this effect may be enhanced more than when the PT is performed under the H-containing gas atmosphere.

Further, when the PT is performed under an O-containing gas atmosphere, it is possible to allow the third film to contain O, and it is possible to allow the third film to become, for example, a silicon oxynitride film (SiON film) that contains Si, O, and N, or a silicon oxycarbonitride film (SiOCN film) that contains Si, O, C, and N. In addition to this method, it is also possible to allow the third film to contain O by unloading the wafers 200 with the third film formed on the surface thereof from the inside of the process chamber 201 and exposing the wafers 200 to an atmosphere.

### (Etching)

After forming the third film, which is a non-flowable film, on the first and second films, i.e., on the initial layer formed on the first and second films, the output of the heater 207 is regulated so as to change the temperature of the wafers 200 to a fourth temperature, which is lower than the third temperature described above (lowering temperature). Then, in a state where the temperature of the wafers 200 reaches the fourth temperature to be stabilized, etching is performed.

In the etching, the surface of the wafer 200 on which the third film is formed on the first and second films via the initial layer is exposed to an etching agent that reacts with the first film. Specifically, the valve 243d is opened to allow the etching agent to flow through the gas supply pipe 232d. A flow rate of the etching agent is regulated by the MFC 241d. The etching agent is supplied into the process chamber 201 via the nozzle 249b and exhausted via the exhaust port 231a. At this time, the etching agent is supplied to the wafer 200 on which the third film is formed on the first and second films via the initial layer (etching agent exposure). At this time, the valves 243e to 243g may be opened to supply an inert gas into the process chamber 201 via each of the nozzles 249a to 249c.

After a predetermined time elapses, the valve 243d is closed to stop the supply of the etching agent into the process chamber 201. Then, gases remaining in the process chamber 201 are removed from the inside of the process chamber 201 by the same processing procedure as the purging in step A1.

As the etching agent, a substance whose reactivity with the first film is higher than each of a reactivity with the second film, a reactivity with the initial layer and a reactivity with the third film may be used.

For example, a fluorine (F)-containing gas may be used as the etching agent. For example, a chlorine trifluoride (ClF₃) gas, a chlorine fluoride (ClF) gas, a nitrogen fluoride (NF₃) gas, a hydrogen fluoride (HF) gas, a fluorine (F₂) gas, or the like may be used as the F-containing gas. Further, various cleaning solutions may be used as the etching agent. For example, a HF aqueous solution may be used as the etching agent to perform DHF cleaning. Further, for example, a cleaning solution containing ammonia water, hydrogen peroxide water, and pure water may be used as the etching agent to perform SC-1 cleaning (APM cleaning). Further, for example, a cleaning solution containing hydrochloric acid, hydrogen peroxide water, and pure water may be used as the etching agent to perform SC-2 cleaning (HPM cleaning). Further, for example, a cleaning solution containing sulfuric acid and hydrogen peroxide water may be used as the etching agent to perform SPM cleaning. One or more of these cleaning solutions may be used as the etching agent.

Processing conditions when supplying the etching agent during the etching are exemplified as follows:
Processing temperature (fourth temperature): room temperature (25 degrees C.) to 300 degrees C., specifically 50 to 150 degrees C.
Processing pressure: 1 to 13,332 Pa, specifically 100 to 3,990 Pa
Supply flow rate of etching agent: 0.05 to 5 slm, specifically 0.1 to 2 slm
Supply time of etching agent: 0.1 to 3 hours, specifically 0.1 to 1 hour
Supply flow rate of inert gas (for each gas supply pipe): 0 to 20 slm, specifically 0.01 to 10 slm.

The supply time of etching agent is synonymous with the etching agent exposure time.

By exposing the surface of the wafer 200 to the etching agent under the above-mentioned processing conditions, the etching agent penetrates the third film and further penetrates the initial layer to reach the first film and the second film. In a case where the second film is a SiN film containing nitrogen (N) or a film containing a metal element, an etching resistance of the second film is higher than an etching resistance of the first film. Further, in a case where the initial layer or the third film is a SiCN film containing carbon (C) in the form of, for example, a Si—C bond or a Si—CH₃ bond, or a SiN film containing nitrogen (N), an etching resistance of the initial layer or the third film is higher than an etching resistance of the first film. As a result, in this step, it is possible to selectively remove (etch) the first film while retaining the second film, the initial layer, and the third film. By selectively removing the first film while retaining the second film, the initial layer, and the third film, as shown in FIG. 5D, it is possible to form an air gap, which is a closed space (void) surrounded by the second film, the initial layer, the third film, and the like, on the wafer 200 with high accuracy. An amount of the first film removed, i.e., a size of the air gap, may be regulated arbitrarily by appropriately selecting processing conditions in the etching within a range of the above-mentioned processing conditions. For example, by removing the entire first film from the surface of the wafer 200, the size of the air gap formed on the surface of the wafer 200 may be increased to a desired size.

### (Fourth Film Formation)

After the air gap is formed on the wafer 200, the fourth film is formed. When forming the fourth film, the output of the heater 207 is regulated so as to change the temperature of the wafer 200 to a fifth temperature higher than the fourth temperature described above (raising temperature). Then, in a state where the temperature of the wafer 200 reaches the fifth temperature to be stabilized, the following steps C1 and C2 are performed.

### [Step C1]

In step C1, the precursor is supplied to the wafers 200 in the process chamber 201. A processing procedure when supplying the precursor may be the same as the processing procedure in step A1 described above. As the precursor, a predetermined precursor may be arbitrarily selected from the various precursors exemplified in step A1. The precursor used in step C1 and the precursor used in step A1 may contain the same molecular structure or different molecular structures.

### [Step C2]

In step C2, the first reactant or the second reactant is supplied to the wafers 200 in the process chamber 201. The processing procedure when supplying the first reactant or the second reactant may be the same as the procedure in step A2 described above. As the first reactant or the second reactant, a predetermined reactant may be arbitrarily selected from the various reactants exemplified in step A2. The reactant used in step C2 and the reactant used in step A2 may contain the same molecular structure or different molecular structures.

### [Performing Predetermined Number of Times]

A cycle including the above-mentioned steps C1 and C2, i.e., a cycle in which C1 and C2 are performed non-simultaneously, is performed a predetermined number of times (n₃ times where n₃ is an integer of 1 or 2 or more). At this time, when the precursor is present alone, the above-mentioned cycle is performed a predetermined number of times under a condition in which chemical adsorption or thermal decomposition of the precursor occurs more predominantly than physical adsorption of the precursor.

Processing conditions when supplying the precursor in step C1 are exemplified as follows:
Processing temperature (fifth temperature): 350 to 700 degrees C., specifically 450 to 650 degrees C.
Processing pressure: 1 to 2,666 Pa, specifically 67 to 1,333 Pa
Supply flow rate of precursor: 0.001 to 2 slm, specifically 0.01 to 1 slm
Supply time of precursor: 1 to 120 seconds, specifically 1 to 60 seconds.
Supply flow rate of inert gas (for each gas supply pipe): 0 to 20 slm, specifically 0.01 to 10 slm.

Processing conditions when supplying the first reactant or the second reactant in step C2 are exemplified as follows:
Processing pressure: 1 to 4,000 Pa, specifically 1 to 3,000 Pa
Supply flow rate of first reactant or second reactant: 0.001 to 20 slm, specifically 1 to 10 slm
Supply time of first reactant or second reactant: 1 to 120 seconds, specifically 1 to 60 seconds.

Other processing conditions may be the same as the processing conditions used when supplying the precursor in step C1.

By supplying the precursor in step C1 under the above-mentioned processing conditions, a portion of the molecular structure of the molecule of the precursor may be adsorbed on the surface of the third film in step C1. Further, by supplying the first reactant or the second reactant in step C2 under the above-mentioned processing conditions, a portion of the molecular structure of the molecule of the precursor adsorbed on the surface of the third film may be caused to react with the first reactant or the second reactant in step C2 to form a non-flowable layer. Then, by performing the above-mentioned cycle a predetermined number of times under the above-mentioned processing conditions, as shown in FIG. 5E, a Si- and N-containing film such as a SiN film or a Si-, C-, and N-containing film such as a SiCN film may be formed as a fourth film on the third film. The fourth film is a non-flowable film.

The above-mentioned cycle may be performed a plurality of times. That is, a thickness of the non-flowable layer formed per cycle is set to be smaller than a desired thickness, and the above-mentioned cycle may be performed a plurality of times until a thickness of the fourth film formed by stacking the non-flowable layers reaches the desired thickness.

In step C2, instead of the various reactants (the N- and H-containing gas) exemplified in step A2, it is possible to supply an O-containing gas such as a H₂O gas or an O₂ gas as the first reactant or the second reactant, and it is also possible to further add the above-mentioned O-containing gas to the various reactants exemplified in step A2 and supply the same. In these cases, it is possible to form a silicon oxide film (SiO film), a silicon oxycarbide film (SiOC film), a silicon oxycarbonitride film (SiOCN film), or a silicon oxynitride film (SiON film) as the fourth film. In addition, in the formation of the fourth film, step C2 of supplying the first reactant or the second reactant may not be performed. In this case, it is possible to form a silicon film (Si film) as the fourth film.

### (After-Purge and Returning to Atmospheric Pressure)

After the fourth film formation is completed, an inert gas as a purge gas is supplied into the process chamber 201 from each of the nozzles 249a to 249c and is exhausted via the exhaust port 231a. Thus, the inside of the process chamber 201 is purged such that gases, reaction by-products, and the like remaining in the process chamber 201 are removed from the inside of the process chamber 201 (after-purge). Thereafter, the internal atmosphere of the process chamber 201 is replaced with an inert gas (replacement of inert gas) and the internal pressure of the process chamber 201 is returned to the atmospheric pressure (returning to atmospheric pressure).

### (Boat Unloading and Wafer Discharging)

Thereafter, the seal cap 219 is moved down by the boat elevator 115 to open the lower end of the manifold 209. Then, the processed wafers 200 supported by the boat 217 are unloaded from the lower end of the manifold 209 to the outside of the reaction tube 203 (boat unloading). After the boat is unloaded, the shutter 219s is moved and the lower end opening of the manifold 209 is sealed by the shutter 219s via the O-ring 220c (shutter closing). The processed wafers 200 are unloaded from the reaction tube 203 and are then discharged from the boat 217 (wafer discharging).

### (3) Effects of the Embodiments

According to the embodiments of the present disclosure, one or more of the following effects may be obtained.

(a) By performing the initial layer formation, the third film formation, and the etching on the wafer 200 including the first film and the second film on the surface thereof, it is possible to etch the first film with high selectivity while suppressing the etching of the second film, the initial layer, and the third film. This makes it possible to precisely form an air gap on the surface of the wafer 200 with high accuracy. As described above, the initial layer formation may be omitted. In the case where the initial layer formation is omitted, by performing the third film formation and the etching on the wafer 200 including the first film and the second film on the surface thereof, it is possible to etch the first film with high selectivity while suppressing the etching of the second film and the third film. This makes it possible to precisely form an air gap on the surface of the wafer 200 with high accuracy.

(b) In the third film formation, it is possible to form the third film that is a continuous film and is capable of effectively transmitting the etching agent. This makes it possible to bring the etching agent into contact with the first film without processing the third film, for example, providing a flow port (opening) in the third film to allow the etching agent to flow downward. In other words, it is possible to omit complicated steps otherwise performed in the related art when forming the air gap, which makes it possible to simplify the process and efficiently form the air gap. As a result, it is possible to shorten a total processing time and significantly improve a productivity.

(c) By using the substance whose reactivity with the first film is higher than each of the reactivity with the second film, the reactivity with the initial layer, and the reactivity with the third film, as the etching agent, it is possible to promote the etching of the first film by the etching agent while suppressing the etching of the second film, the initial layer, and the third film by the etching agent, and it becomes possible to effectively selectively remove the first film among the first film, the second film, the initial layer, and the third film. As described above, the initial layer formation may be omitted. In the case where the initial layer formation is omitted, by using the substance whose reactivity with the first film is higher than each of the reactivity with the second film and the reactivity with the third film as the etching agent, it is possible to promote the etching of the first film by the etching agent while suppressing the etching of the second film and the third film by the etching agent, and it is possible to effectively perform a selective removal of the first film among the first film, the second film, and the third film.

(d) By performing the initial layer formation and the third film formation in this order, and forming the non-flowable initial layer at a temperature higher than the temperature during the flowable film formation before forming the flowable film on the first film and the second film, it is possible to block influence of a surface state of the base in the film formation process. As a result, it is possible to suppress abnormal growth of the flowable film on the first film and the second film and occurrence of film formation defects, and it is possible to appropriately form a conformal and continuous third film.

The abnormal growth mentioned above means, for example, that a film to be formed on the wafer 200 grows in a so-called droplet shape (island shape) under the influence of the surface state of the first film that is a portion of the base in the film-forming process, i.e., under the influence of OH (hydroxyl group) termination on the surface of the O-containing film. The abnormal growth may reduce a wafer in-plane film thickness uniformity of the film to be formed on the wafer 200. Further, the abnormal growth may also deteriorate a surface roughness (flatness) of the film to be formed on the wafer 200. In addition, the abnormal growth may also be a cause of particle generation in the process chamber 201.

(e) By performing the fourth film formation after the etching, it is possible to laminate the fourth film with a higher density than the third film on the third film, and it is possible to reinforce the third film with a low density by the fourth film with a high density. As a result, it is possible to increase a strength of the entire laminated film constituted by the third film and the fourth film.

(f) Since the first film and the second film are alternately arranged so as to be adjacent to each other on the surface of the wafer 200 before the third film is formed, it is possible to form a plurality of air gaps so as to be precisely adjacent to each other.

(g) When the precursor contains silicon, the first reactant contains nitrogen and hydrogen, the second reactant contains nitrogen and hydrogen, and the second reactant contains a molecular structure different from that of the first reactant, the above-mentioned effects may be more remarkable, and an accuracy of formation of the air gap may be further enhanced.

(h) When at least one selected from the group of the precursor and the first reactant contains an alkyl group, the etching of the third film by the etching agent may be more effectively suppressed, and an accuracy of formation of the air gap may be further enhanced.

(i) When the precursor contains a halogeno group and an alkyl group and the first reactant contains an alkyl group, the etching of the third film by the etching agent may be more effectively suppressed, and the accuracy of formation of the air gap may be further enhanced.

(j) When the precursor is alkylhalosilane, the first reactant is amine or organic hydrazine, and the second reactant is hydrogen nitride, the etching of the third film by the etching agent may be more effectively suppressed, and the accuracy of formation of the air gap may be further enhanced.

(k) When the first film contains a semiconductor element and oxygen, the selective etching of the first film by the etching agent may be further promoted, and the accuracy of formation of the air gap may be further enhanced.

(l) When the second film contains a semiconductor element and nitrogen or contains a metal element, the etching of the second film by the etching agent may be more effectively suppressed, and the accuracy of formation of the air gap may be further enhanced.

(m) When the third film contains a semiconductor element, carbon, and nitrogen, the etching of the third film by the etching agent may be more effectively suppressed, and the accuracy of formation of the air gap may be further enhanced.

(n) When the etching agent contains fluorine and hydrogen, the first film may be etched with high selectivity while suppressing the etching of the second film and the third film, and the accuracy of formation of the air gap may be further enhanced. The etching agent may be a gaseous substance, a liquid substance, or may contain both. The etching agent may be, for example, an aqueous solution containing fluorine and hydrogen. When the etching agent is an aqueous solution, it is possible to etch the first film with high selectivity at a high etching rate without leaving any residue.

(o) The initial layer formation, the third film formation, the etching, and the fourth film formation may be performed in a non-plasma atmosphere, which makes it possible to prevent plasma damage to the wafer 200 and the like.

(p) The above-mentioned effects may be obtained similarly even when a predetermined substance (gaseous substance, or liquid substance) is arbitrarily selected from the various precursors, reactants, etching agents, and inert gases described above.

### <Other Embodiments of Present Disclosure>

Various embodiments of the present disclosure are specifically described above. However, the present disclosure is not limited to the above-described embodiments, and various modifications may be made without departing from the gist of the disclosure.

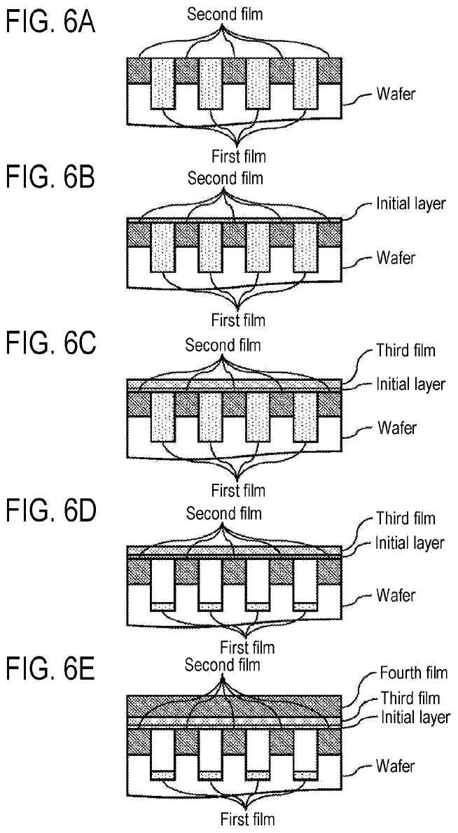

For example, in the above-described embodiments, the case are described in which the first film and the second film are alternately arranged on the flat surface of the wafer in parallel to the flat surface. However, the present disclosure is not limited thereto. For example, as shown in FIG. 6A, as the substrate which is a processing target, it may be possible to use a wafer in which a plurality of recesses such as trenches are formed on the surface thereof at predetermined intervals and first films formed to fill the respective recesses and second films formed outside the recesses are alternately arranged.

In these embodiments, by performing the initial layer formation under the processing procedure and processing conditions used in the above-described embodiments, it is possible to form a non-flowable initial layer on the first film and the second film as shown in FIG. 6B. Further, by performing the third film formation under the processing procedure and processing conditions used in the above-described embodiments, it is possible to form the third film, which is a continuous non-flowable film, on the first film and the second film, i.e., on the initial layer formed on the first film and the second film, as shown in FIG. 6C. Further, by performing the etching under the processing procedure and processing conditions used in the above-described embodiments, it is possible to selectively remove the first film while retaining the second film, the initial layer, and the third film, and to precisely form the air gap on the surface of the wafer 200 with high accuracy as shown in FIG. 6D. Further, by performing the fourth film formation under the processing procedure and processing conditions used in the above-described embodiments, it is possible to form the fourth film with a high density on the third film with a low density as shown in FIG. 6E.

In these embodiments, the same effects as in the above-described embodiments may be obtained. In these embodiments, an amount of the first film removed, i.e., a size of the air gap, may be arbitrarily regulated by appropriately selecting the processing conditions in the etching within a range of the above-mentioned processing conditions. For example, the entire first film may be removed from an inside of the recess formed on the surface of the wafer. Alternatively, for example, as shown in FIG. 6D, a portion of the first film may be left in the recess formed on the surface of the wafer.

For example, in the above-described embodiments, the example is described in which the initial layer formation is performed before the third film formation. However, the present disclosure is not limited to thereto, and the initial layer formation may not be performed before the third film formation. Further, instead of the initial layer formation, a treatment (a hydrophobization treatment) to hydrophobize the surfaces of the first film and the second film may be performed. As the treatment, it may be possible to perform plasma processing, annealing, nitriding (plasma nitriding, or thermal nitriding), and the like. As a result, the surfaces of the first film and the second film may be made non-hydrophilic (hydrophobic) without performing the initial layer formation. Further, in the above-described embodiments, the example is described in which the PT is performed after the flowable film formation. However, the present disclosure is not limited thereto, and the PT may not be performed after the flowable film formation. Further, in the above-described embodiments, the example is described in which the fourth film formation is performed after the etching. However, the present disclosure is not limited thereto, and the fourth film formation may not be formed after the etching. In these embodiments, the same effects as those of the above-described embodiments may be obtained.

Further, for example, in the above-described embodiments, the example is described in which the etching is performed after the third film formation. However, the present disclosure is not limited thereto. After the third film formation and before the etching, the third film formed on the substrate may be heat-treated at a temperature in the range of, for example, 400 to 600 degrees C. This makes it possible to further increase the hardness of the third film. The heat treatment may be performed under the same processing procedure and processing conditions as those of the PT.

Further, for example, in the above-described embodiments, the example is described in which a series of steps from the initial layer formation to the fourth film formation are performed in the same process chamber 201 of the substrate processing system (in-situ). However, the present disclosure is not limited thereto. For example, among the series of steps, a specific step, for example, a step such as the PT or the etching, may be performed in another process chamber of the substrate processing system (ex-situ). For example, a substrate processing system including a plurality of stand-alone substrate processing apparatuses (a first substrate processing apparatus, a second substrate processing apparatus, a third substrate processing apparatus, etc.) may be used to perform the respective steps in different process chambers of the different substrate processing apparatuses, i.e., in different processors. Further, for example, a substrate processing system including a cluster type substrate processing apparatus in which a plurality of process chambers (a first process chamber, a second process chamber, a third process chamber, etc.) are installed around a transfer chamber may be used to perform the respective steps in different process chambers of the same substrate processing apparatus, i.e., in different processors. In these cases, the same effects as those of the above-described embodiments may be obtained.

For example, in the above-described embodiments, as the main example, the second film is a film containing a semiconductor element and nitrogen. However, the present disclosure is not limited thereto. For example, even in a case where the second film is a film containing a metal element such as aluminum (Al), titanium (Ti), hafnium (Hf), zirconium (Zr), tantalum (Ta), molybdenum (Mo), copper (Cu), cobalt (Co), tungsten (W), ruthenium (Ru), or the like, the same effects as those of the above-described embodiments may be obtained.

Further, for example, in the above-described embodiments, as a main example, the case is described in which the third film is a SiN film or a SiCN film. However, the present disclosure is not limited thereto. For example, even in a case where the third film is a film containing a semiconductor element, such as a SiOC film, a SiOCN film, a SiON film, or a Si film, the same effects as those of the above-described embodiments may be obtained.

Further, for example, in the above-described embodiments, as a main example, the case is described in which the fourth film is a SiN film or a SiCN film. However, the present disclosure is not limited thereto. For example, even in a case where the fourth film is a film containing a semiconductor element, such as a SiO film, a SiOC film, a SiOCN film, a SiON film, or a Si film, the same effects as those of the above-described embodiments may be obtained.

The recipes used in the respective processes may be provided individually according to the processing contents and may be recorded and stored in the memory 121c via a telecommunication line or the external memory 123. Moreover, at the beginning of each process, the CPU 121a may properly select an appropriate recipe from a plurality of recipes recorded and stored in the memory 121c according to the processing contents. Thus, it is possible to form films of various types, composition ratios, qualities, and thicknesses with enhanced reproducibility in a substrate processing apparatus. Further, it is possible to reduce an operator's burden and to quickly start each process while avoiding an operation error.

The recipes mentioned above are not limited to newly-provided ones but may be provided, for example, by modifying existing recipes that are already installed in the processing apparatus. Once the recipes are modified, the modified recipes may be installed in the processing apparatus via a telecommunication line or a recording medium storing the recipes. Further, the existing recipes already installed in the existing substrate processing apparatus may be directly modified by operating the input/output device 122 of the substrate processing apparatus.

An example in which a film is formed by using a batch-type substrate processing apparatus configured to process a plurality of substrates at a time is described in the above-described embodiments of the present disclosure. The present disclosure is not limited to the above-described embodiments of the present disclosure, but may be suitably applied, for example, to a case where a film is formed by using a single-wafer type substrate processing apparatus configured to process a single substrate or several substrates at a time. Further, the example in which a film is formed by using a substrate processing apparatus including a hot-wall-type process furnace is described above in the above-described embodiments. The present disclosure is not limited to the above-described embodiments, but may be suitably applied to a case where a film is formed by using a substrate processing apparatus including a cold-wall-type process furnace.

Even in the case where these substrate processing apparatuses are used, each process may be performed under the same processing procedures and processing conditions as those of the above-described embodiments and modifications. The same effects as those of the above-described embodiments and modifications may be obtained.

The above-described embodiments and modifications may be used in appropriate combination. Processing procedures and processing conditions used in such a case may be the same as those of the above-described embodiments and modifications.

### Example

An air gap is formed on the surface of the substrate by the processing sequence in the embodiments described above, and TEM images of a surface of a wafer during the formation process are taken.

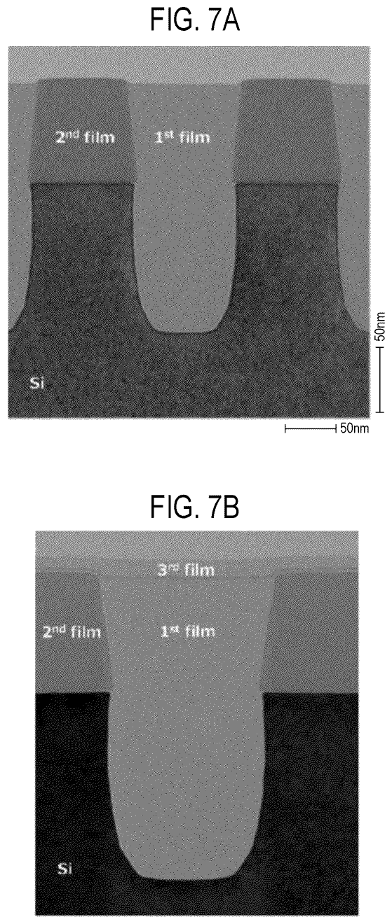

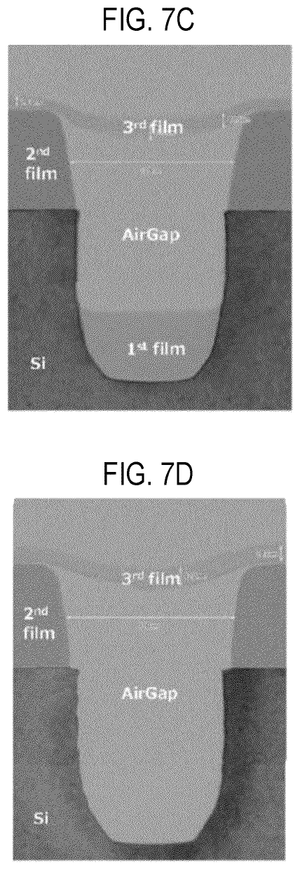

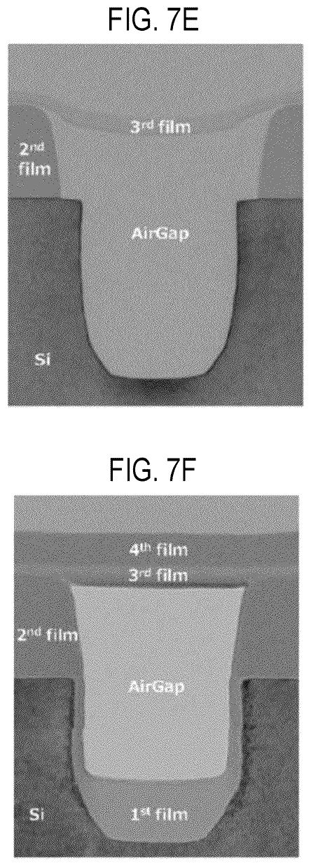

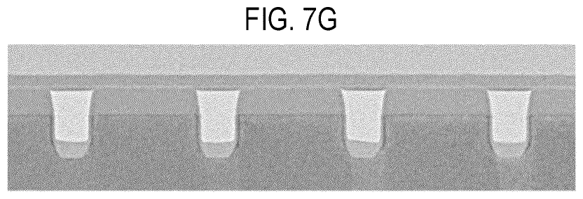

Specifically, as a substrate which is a processing target, a Si wafer is provided in which a plurality of recesses are formed on a surface thereof and first films formed to fill the recesses and second films formed outside the recesses are arranged alternately so as to be adjacent to each other. FIG. 7A shows a TEM image of the surface of the wafer in the example.

For this wafer, an initial layer and a third film are sequentially formed on the first film and the second film by the same processing procedure and processing conditions as the initial layer formation and the third film formation in the above-described embodiments. FIG. 7B shows that a TEM image of the surface of the wafer in the example after the third film is formed. As shown in this TEM image, it may be seen that the third film is continuously formed on the first film and the second film.

Next, the surface of the wafer after the third film is formed is exposed to an etching agent to be etched. The etching is performed according to the same procedure and conditions as those of the etching performed in the above-described embodiments. TEM images of the surface of the wafer in the example after the etching with etching agent exposure times of 30 minutes, 60 minutes, and 90 minutes are shown in order in FIGS. 7C to 7E. From these images, it may be seen that by performing the etching, it is possible to selectively remove the first film while retaining the second film and the third film, and form an air gap on the wafer with high accuracy. Further, it may be seen that an amount of the first film removed, i.e., a size of the air gap, may be arbitrarily controlled by appropriately selecting processing conditions (exposure time) in the etching within the range of the processing conditions in the etching of the above-described embodiments.

Next, a fourth film is formed on the wafer after formation of the air gap by the same processing procedure and processing conditions as those of the fourth film formation in the above-described embodiments. FIGS. 7F and 7G show TEM images of the surface of the wafer in the example after performing etching with the etching agent exposure time of 25 minutes, forming an air gap, and then forming a fourth film on the third film. FIG. 7F is a TEM image obtained by partially enlarging the image shown in FIG. 7G. From these TEM images, it may be noted that multiple air gaps may be precisely formed on the wafer with high accuracy.

According to the present disclosure in some embodiments, it is possible precisely form an air gap with high accuracy.

While certain embodiments are described above, these embodiments are presented by way of example, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
(a) forming a third film on a first film and a second film formed on a surface of the substrate by supplying a precursor, a first reactant, and a second reactant to the substrate under a condition in which thermal decomposition of the precursor does not occur and physical adsorption of the precursor occurs more predominantly than chemical adsorption of the precursor when the precursor is present alone; and
(b) removing the first film while retaining the second film and the third film by exposing the surface of the substrate where the third film is formed on the first film and the second film to an etching agent that reacts with the first film.

2. The method of claim 1, wherein in (a), the third film is formed by causing an oligomer containing an element contained in at least one selected from the group of the precursor, the first reactant, and the second reactant to flow on the first film and the second film.

3. The method of claim 1, wherein reactivity of the etching agent with the first film is higher than each of reactivity of the etching agent with the second film and reactivity of the etching agent with the third film.

4. The method of claim 1, wherein in (a), before forming the third film, an initial layer is formed on the first film and the second film by supplying the precursor and the first reactant or the second reactant under a condition in which the chemical adsorption or the thermal decomposition of the precursor occurs more predominantly than the physical adsorption of the precursor when the precursor is present alone, and the third film is formed on the initial layer.

5. The method of claim 4, wherein the initial layer is a non-flowable layer, and the third film is a flowable film at least during a formation process of the third film.

6. The method of claim 2, further comprising (c) forming a non-flowable film as a fourth film on the third film after performing (b).

7. The method of claim 1, wherein on the surface of the substrate before the third film is formed, the first film and the second film are alternately arranged while being adjacent to each other.

8. The method of claim 1, wherein the precursor contains silicon, the first reactant contains nitrogen and hydrogen, the second reactant contains nitrogen and hydrogen, and a molecular structure of the second reactant is different from a molecular structure of the first reactant.

9. The method of claim 1, wherein at least one selected from the group of the precursor and the first reactant contains an alkyl group.

10. The method of claim 1, wherein the precursor contains a halogen group and an alkyl group, and the first reactant contains an alkyl group.

11. The method of claim 1, wherein the precursor is alkylhalosilane, the first reactant is amine or organic hydrazine, and the second reactant is hydrogen nitride.

12. The method of claim 1, wherein the first film contains a semiconductor element and oxygen.

13. The method of claim 1, wherein the second film contains a semiconductor element and nitrogen, or contains a metal element.

14. The method of claim 1, wherein the third film contains a semiconductor element, carbon, and nitrogen.

15. The method of claim 1, wherein the third film exposed to the etching agent in (b) is a continuous film.

16. The method of claim 1, wherein the etching agent contains fluorine and hydrogen.

17. The method of claim 1, wherein (a) and (b) are performed in a non-plasma atmosphere.

18. A method of manufacturing a semiconductor device, comprising the method of claim 1.

19. A substrate processing system, comprising:
a precursor supply system configured to supply a precursor to a substrate;
a first reactant supply system configured to supply a first reactant to the substrate;
a second reactant supply system configured to supply a second reactant to the substrate;
an etching agent exposure system configured to expose the substrate to an etching agent;
a heater configured to heat the substrate; and
a controller configured to be capable of controlling the precursor supply system, the first reactant supply system, the second reactant supply system, the etching agent exposure system, and the heater to perform a process including:
(a) forming a third film on a first film and a second film formed on a surface of the substrate by supplying the precursor, the first reactant, and the second reactant to the substrate under a condition in which thermal decomposition of the precursor does not occur and physical adsorption of the precursor occurs more predominantly than chemical adsorption of the precursor when the precursor is present alone; and
(b) removing the first film while retaining the second film and the third film by exposing the surface of the substrate where the third film is formed on the first film and the second film to the etching agent that reacts with the first film.

20. A non-transitory computer-readable recording medium storing a program that causes, by a computer, a substrate processing system to perform a process comprising:
(a) forming a third film on a first film and a second film formed on a surface of a substrate by supplying a precursor, a first reactant, and a second reactant to the substrate under a condition in which thermal decomposition of the precursor does not occur and physical adsorption of the precursor occurs more predominantly than chemical adsorption of the precursor when the precursor is present alone; and
(b) removing the first film while retaining the second film and the third film by exposing the surface of the substrate where the third film is formed on the first film and the second film to an etching agent that reacts with the first film.
